(19) United States
(12) Patent Application Publication
(10) Pub. No.: US 2025/0147322 A1
(43) Pub. Date: May 8, 2025

(54) Projector for Use in a Head-Mounted Display Device System

(71) Applicant: Ticona LLC, Florence, KY (US)

(72) Inventors: Yiqin Wang, Shanghai (CN); Shuai Xu, Shanghai (CN); Young Shin Kim, Cincinnati, OH (US); Fangfang Tao, Shanghai (CN)

(21) Appl. No.: 18/700,738

(22) PCT Filed: Sep. 21, 2022
(86) PCT No.: PCT/CN2022/120135

§ 371 Date: Apr. 12, 2024

(51) Int. Cl. G02B 27/01; C09K 19/38; C09K 19/52; G03B 21/14; G03B 21/16; H01S 5/024

(52) U.S. Cl. CPC G02B 27/0176; C09K 19/3809; C09K 19/52; G03B 21/145; G03B 21/16; C09K 2019/521; G02B 2027/0178; H01S 5/02469

(57) ABSTRACT

A projector for use in a head-mounted display system is provided. The projector comprises an illumination source and an optical display that is capable of producing an image derived from light emitted by the illumination source. The projector contains a polymer matrix that contains a thermoplastic polymer, wherein the polymer composition exhibits a deflection temperature under load of about 50° C. or more as determined in accordance with ISO 75: 2013 at a load of 1.8 MPa.

### BACKGROUND OF THE INVENTION

Head-mounted display systems (e.g., virtual, mixed, and augmented reality systems) generally contain one or more projectors that are integrally connected to one or more lenses or frames of the system. The position and/or orientation of the projector is often carefully selected to promote the functionality of the device—e.g., a positioning component may be affixed to a location that determines the orientation of the device, but may only be accurate if the actual position and orientation matches an expected position and orientation. In such cases, the relative position of the projector to other components may be significant in that even a small divergence in the position and/or orientation may disrupt the stereoscopic presentation. Heat generated by the projector can also lead to a further decline in its dimensional stability, thereby further distorting the resulting visual image. As such, a need currently exists for projectors that can be more readily employed in head-mounted display systems.

### SUMMARY OF THE INVENTION

In accordance with one embodiment of the present invention, a projector for use in a head-mounted display system is disclosed. The projector comprises an illumination source and an optical display that is capable of producing an image derived from light emitted by the illumination source. The projector contains a polymer matrix that contains a thermoplastic polymer, wherein the polymer composition exhibits a deflection temperature under load of about 50° C. or more as determined in accordance with ISO 75:2013 at a load of 1.8 MPa.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 depicts one embodiment of a head-mounted display system that may contain the projector of the present invention;

FIG. 2 depicts one embodiment of the projector of the present invention; and

FIG. 3 depicts one embodiment of an optical waveguide and a correction lens that may be employed in the projector of the present invention.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a projector (e.g., nanoprojector, picoprojector, microprojector, femtoprojector, LASER-based projector, holographic projector, etc.) for use in a head-mounted, virtual, mixed, and/or augmented reality display system. The projector generally includes an optical display that is capable of producing a visual image derived from light emitted by an illumination source. Notably, the projector contains a polymer composition that includes a high performance thermoplastic polymer. In this manner, the deflection temperature under load (“DTUL”), a measure of short term heat resistance may remain relatively high. For instance, the DTUL may be about 50° C. or more, in some embodiments about 55° C. or more, in some embodiments about 60° C. or more, in some embodiments from about from about 100° C. to about 350° C., in some embodiments from about 170° C. to about 320° C., in some embodiments from about 210° C. to about 300° C., and in some embodiments, from about 220° C. to about 280° C., such as determined in accordance with ISO 75:2013 at a load of 1.8 MPa. Even at such DTUL values, the ratio of the melting temperature to the DTUL value may still remain relatively high. For example, the ratio may range from about 0.5 to about 1.00, in some embodiments from about 0.6 to about 0.95, and in some embodiments, from about 0.65 to about 0.85. The specific melting temperature of the polymer composition may, for instance, be about 140° C. or more, in some embodiments about about 150° C. or more, in some embodiments from about 200° C. to about 440° C., in some embodiments from about 250° C. to about 420° C., in some embodiments from about 260° C. to about 400° C., and in some embodiments, from about 300° C. to about 380° C. The glass transition and melting temperatures may be determined as is well known in the art using differential scanning calorimetry (“DSC”), such as determined by ISO 11357-2:2020 (glass transition) and 11357-3:2018 (melting).

The high performance polymer composition can exhibit good dimensional stability, which can help improve the accuracy of the alignment and positioning of the projector within the head-mounted display. More particularly, the polymer composition may exhibit a dimensional stability of about 6 or less, in some embodiments about 5 or less, in some embodiments from about 0.5 to about 5, and in some embodiments, from about 1 to about 4.5. The “dimensional stability” may be determined by dividing the degree of shrinkage in the transverse direction by the degree of shrinkage in the machine direction, which may be determined in accordance with ISO 294-4:2018 at a certain temperature (e.g., 25° C. or 70° C.) using a Type D2 specimen (technically equivalent to ASTM D955-08(2014)). The degree of shrinkage in the transverse direction (“S_{T}”) may, for instance, be from about 0.2% to about 1.5%, in some embodiments from about 0.4% to about 1.2%, and in some embodiments, from about 0.5% to about 1.0%, while the degree of shrinkage in the machine direction (“S_{F}”) may be from about 0.02% to about 0.6%, in some embodiments from 0.05% to about 0.5%, and in some embodiments, from about 0.1% to about 0.4%.

The polymer composition may also exhibit a high degree of flowability. For example, the polymer composition may exhibit a melt viscosity of about 700 Pa-s or less, in some embodiments about 600 Pa-s or less, in some embodiments about 500 Pa-s or less, in some embodiments about 300 Pa-s or less, in some embodiments about 150 Pa-s or less, in some embodiments from about 5 to about 100 Pa-s, in some embodiments from about 10 to about 95 Pa-s, and in some embodiments, from about 15 to about 80 Pa-s, as determined in accordance with ISO 11443:2021 at a shear rate of 1,000 s⁻¹ or 1,200 s⁻¹ and at a temperature above the melting temperature of the composition. The polymer composition may likewise exhibit a melt volume flow rate (“MVR”) of about 500 cm³/10 min or less, in some embodiments about 250 cm³/10 min or less, and in some embodiments, from about 40 to about 150 cm³/10 min, as determined at a temperature of 275° C. and load of 5 kilograms in accordance with ISO 1133:2011.

While being heat resistant and having good flow properties, the polymer composition may nevertheless may be electrically insulative and maintain a high degree of short-term dielectric strength even when exposed to an electric field. The “dielectric strength” generally refers to the voltage that the material can withstand before breakdown occurs. For instance, the polymer composition may generally exhibit a dielectric strength of about 10 kilovolts per millimeter (kV/mm) or more, in some embodiments about 15 kV/mm or more, and in some embodiments, from about 25 kV/mm to about 60 kV/mm, such as determined in accordance with IEC 60234-1:2013. The insulative properties of the polymer composition may also be characterized by a high comparative tracking index (“CTI”), such as about 150 volts or more, in some embodiments about 170 volts or more, in some embodiments about 200 volts or more, and in some embodiments, from about 220 to about 350 volts, such as determined in accordance with IEC 60112:2003 at a thickness of 3 millimeters.

Despite having the properties noted above, the polymer composition may nevertheless maintain a high degree of strength, which can provide enhanced flexibility and impact resistance. The polymer composition may, for example, exhibit a tensile stress at break (i.e., strength) of from about 40 MPa to about 300 MPa, in some embodiments from about 50 MPa to about 250 MPa, and in some embodiments, from about 70 to about 200 MPa; a tensile break strain (i.e., elongation) of about 0.5% or more, in some embodiments from about 1% to about 8%, and in some embodiments, from about 2% to about 5%; and/or a tensile modulus of from about 5,000 to about 30,000 MPa, in some embodiments from about 6,000 MPa to about 25,000 MPa, and in some embodiments, from about 9,000 MPa to about 22,000 MPa. The tensile properties may be determined in accordance with ISO 527:2019 at a temperature of 23° C. The composition may also exhibit a flexural strength of about 20 MPa or more, in some embodiments from about 50 to about 300 MPa, in some embodiments from about 70 to about 250 MPa, and in some embodiments, from about 80 to about 200 MPa and/or a flexural modulus of about 10,000 MPa or less, in some embodiments from about 5,000 MPa to about 30,000 MPa, in some embodiments from about 8,000 MPa to about 25,000 MPa, and in some embodiments, from about 9,000 MPa to about 20,000 MPa. The flexural properties may be determined in accordance with ISO 178:2019 at a temperature of 23° C. The polymer composition may also exhibit a high impact strength, which can provide enhanced flexibility for the resulting part. For example, the polymer composition may exhibit an unnotched Charpy impact strength of about 2 kJ/m² or more, in some embodiments from about 4 to about 20 kJ/m², and in some embodiments, from about 6 to about 18 kJ/m² and/or a notched Charpy impact strength of about 10 kJ/m² or more, in some embodiments from about 15 to about 50 kJ/m², and in some embodiments, from about 20 to about 40 kJ/m², as determined at a temperature of 23° C. in accordance with ISO 179-1:2010.

Various embodiments of the present invention will now be described in more detail.

### I. Polymer Composition

### A. Polymer Matrix

As indicated above, the polymer matrix contains at least one high performance thermoplastic polymer. For example, such polymers typically constitute from about 50 wt. % to 100 wt. %, in some embodiments from about 70 wt. % to 100 wt. %, and in some embodiments, from about 90 wt. % to 100 wt. % of the polymer matrix (e.g., 100 wt. %). The high performance, thermoplastic polymers generally have a high degree of heat resistance, such as reflected by a deflection temperature under load within the ranges noted above. In addition to exhibiting a high degree of heat resistance, the thermoplastic polymers also typically have a high glass transition temperature, such as about 10° C. or more, in some embodiments about 20° C. or more, in some embodiments about 30° C. or more, in some embodiments about 40° C. or more, in some embodiments about 50° C. or more, and in some embodiments, from about 60° C. to about 320° C. When semi-crystalline or crystalline polymers are employed, the high performance polymers may also have a high melting temperature, such as about 140° C. or more, in some embodiments from about 150° C. to about 400° C., and in some embodiments, from about 200° C. to about 380° C. The glass transition and melting temperatures may be determined as is well known in the art using differential scanning calorimetry (“DSC”), such as determined by ISO 11357-2:2020 (glass transition) and 11357-3:2018 (melting).

Suitable high performance, thermoplastic polymers for this purpose may include, for instance, polyamides (e.g., aliphatic, semi-aromatic, or aromatic polyamides), polyarylene sulfides, liquid crystalline polymers (e.g., wholly aromatic polyesters, polyesteramides, etc.), polyesters (e.g., aromatic polyesters), as well as blends thereof. The exact choice of the polymer system will depend upon a variety of factors, such as the nature of other fillers included within the composition, the manner in which the composition is formed and/or processed, and the specific requirements of the intended application.

Aromatic polymers, for instance, are particularly suitable for use in the polymer matrix. The aromatic polymers can be substantially amorphous, semi-crystalline, or crystalline in nature. One example of a suitable semi-crystalline aromatic polymer, for instance, is an aromatic polyester, which may be a condensation product of at least one diol (e.g., aliphatic and/or cycloaliphatic) with at least one aromatic dicarboxylic acid, such as those having from 4 to 20 carbon atoms, and in some embodiments, from 8 to 14 carbon atoms. Suitable diols may include, for instance, neopentyl glycol, cyclohexanedimethanol, 2,2-dimethyl-1,3-propane diol and aliphatic glycols of the formula HO(CH₂)ₙOH where n is an integer of 2 to 10. Suitable aromatic dicarboxylic acids may include, for instance, isophthalic acid, terephthalic acid, 1,2-di(p-carboxyphenyl)ethane, 4,4′-dicarboxydiphenyl ether, etc., as well as combinations thereof. Fused rings can also be present such as in 1,4- or 1,5- or 2,6-naphthalene-dicarboxylic acids. Particular examples of such aromatic polyesters may include, for instance, poly(ethylene terephthalate) (PET), poly(1,4-butylene terephthalate) (PBT), poly(1,3-propylene terephthalate) (PPT), poly(1,4-butylene 2,6-naphthalate) (PBN), poly(ethylene 2,6-naphthalate) (PEN), poly(1,4-cyclohexylene dimethylene terephthalate) (PCT), as well as mixtures of the foregoing.

Derivatives and/or copolymers of aromatic polyesters (e.g., polyethylene terephthalate) may also be employed. For instance, in one embodiment, a modifying acid and/or diol may be used to form a derivative of such polymers. As used herein, the terms “modifying acid” and “modifying diol” are meant to define compounds that can form part of the acid and diol repeat units of a polyester, respectively, and which can modify a polyester to reduce its crystallinity or render the polyester amorphous. Examples of modifying acid components may include, but are not limited to, isophthalic acid, phthalic acid, 1,3-cyclohexanedicarboxylic acid, 1,4-cyclohexane dicarboxylic acid, 2,6-naphthaline dicarboxylic acid, succinic acid, glutaric acid, adipic acid, sebacic acid, suberic acid, 1,12-dodecanedioic acid, etc. In practice, it is often preferable to use a functional acid derivative thereof such as the dimethyl, diethyl, or dipropyl ester of the dicarboxylic acid. The anhydrides or acid halides of these acids also may be employed where practical. Examples of modifying diol components may include, but are not limited to, neopentyl glycol, 1,4-cyclohexanedimethanol, 1,2-propanediol, 1,3-propanediol, 2-methy-1,3-propanediol, 1,4-butanediol, 1,6-hexanediol, 1,2-cyclohexanediol, 1,4-cyclohexanediol, 1,2-cyclohexanedimethanol, 1,3-cyclohexanedimethanol, 2,2,4,4-tetramethyl 1,3-cyclobutane diol, Z,8-bis(hydroxymethyltricyclo-[5.2.1.0]-decane wherein Z represents 3, 4, or 5; 1,4-bis(2-hydroxyethoxy)benzene, 4,4′-bis(2-hydroxyethoxy)diphenylether [bis-hydroxyethyl bisphenol A], 4,4′-Bis(2-hydroxyethoxy)diphenylsulfide [bis-hydroxyethyl bisphenol S] and diols containing one or more oxygen atoms in the chain, e.g. diethylene glycol, triethylene glycol, dipropylene glycol, tripropylene glycol, etc. In general, these diols contain 2 to 18, and in some embodiments, 2 to 8 carbon atoms. Cycloaliphatic diols can be employed in their cis- or trans-configuration or as mixtures of both forms.

The aromatic polyesters, such as described above, typically have a DTUL value of from about 40° C. to about 80° C., in some embodiments from about 45° C. to about 75° C., and in some embodiments, from about 50° C. to about 70° C. as determined in accordance with ISO 75-2:2013 at a load of 1.8 MPa. The aromatic polyesters likewise typically have a glass transition temperature of from about 30° C. to about 120° C., in some embodiments from about 40° C. to about 110° C., and in some embodiments, from about 50° C. to about 100° C., such as determined by ISO 11357-2:2020, as well as a melting temperature of from about 170° C. to about 300° C., in some embodiments from about 190° C. to about 280° C., and in some embodiments, from about 210° C. to about 260° C., such as determined in accordance with ISO 11357-2:2018. The aromatic polyesters may also have an intrinsic viscosity of from about 0.1 dl/g to about 6 dl/g, in some embodiments from about 0.2 to about 5 dl/g, and in some embodiments from about 0.3 to about 1 dl/g, such as determined in accordance with ISO 1628-5:1998.

Polyarylene sulfides may also be suitable semi-crystalline aromatic polymers. The polyarylene sulfide may be homopolymers or copolymers. For instance, selective combination of dihaloaromatic compounds can result in a polyarylene sulfide copolymer containing not less than two different units. For instance, when p-dichlorobenzene is used in combination with m-dichlorobenzene or 4,4′-dichlorodiphenylsulfone, a polyarylene sulfide copolymer can be formed containing segments having the structure of formula:

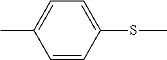

and segments having the structure of formula:

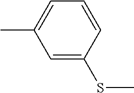

or segments having the structure of formula:

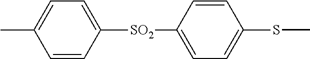

The polyarylene sulfide may be linear, semi-linear, branched or crosslinked. Linear polyarylene sulfides typically contain 80 mol % or more of the repeating unit —(Ar—S)—. Such linear polymers may also include a small amount of a branching unit or a cross-linking unit, but the amount of branching or cross-linking units is typically less than about 1 mol % of the total monomer units of the polyarylene sulfide. A linear polyarylene sulfide polymer may be a random copolymer or a block copolymer containing the above-mentioned repeating unit. Semi-linear polyarylene sulfides may likewise have a cross-linking structure or a branched structure introduced into the polymer a small amount of one or more monomers having three or more reactive functional groups. By way of example, monomer components used in forming a semi-linear polyarylene sulfide can include an amount of polyhaloaromatic compounds having two or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, etc., and mixtures thereof.

The polyarylene sulfides, such as described above, typically have a DTUL value of from about 70° C. to about 220° C., in some embodiments from about 90° C. to about 200° C., and in some embodiments, from about 120° C. to about 180° C. as determined in accordance with ISO 75-2:2013 at a load of 1.8 MPa. The polyarylene sulfides likewise typically have a glass transition temperature of from about 50° C. to about 120° C., in some embodiments from about 60° C. to about 115° C., and in some embodiments, from about 70° C. to about 110° C., such as determined by ISO 11357-2:2020, as well as a melting temperature of from about 220° C. to about 340° C., in some embodiments from about 240° C. to about 320° C., and in some embodiments, from about 260° C. to about 300° C., such as determined in accordance with ISO 11357-3:2018.

In addition to the polymers referenced above, highly crystalline aromatic polymers may also be employed in the polymer composition. Particularly suitable examples of such polymers are liquid crystalline polymers, which have a high degree of crystallinity that enables them to effectively fill the small spaces of a mold. Liquid crystalline polymers are generally classified as “thermotropic” to the extent that they can possess a rod-like structure and exhibit a crystalline behavior in their molten state (e.g., thermotropic nematic state). Such polymer typically have a DTUL value of from about 120° C. to about 340° C., in some embodiments from about 140° C. to about 320° C., and in some embodiments, from about 150° C. to about 300° C., as determined in accordance with ISO 75-2:2013 at a load of 1.8 MPa. The polymers also have a relatively high melting temperature, such as from about 250° C. to about 400° C., in some embodiments from about 280° C. to about 390° C., and in some embodiments, from about 300° C. to about 380° C. Such polymers may be formed from one or more types of repeating units as is known in the art.

A liquid crystalline polymer may, for example, contain one or more aromatic ester repeating units, typically in an amount of from about 60 mol. % to about 99.9 mol. %, in some embodiments from about 70 mol. % to about 99.5 mol. %, and in some embodiments, from about 80 mol. % to about 99 mol. % of the polymer. Liquid crystalline polymers may be formed from one or more types of repeating units as is known in the art. A liquid crystalline polymer may, for example, contain one or more aromatic ester repeating units generally represented by the following Formula (I):

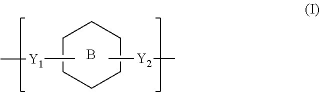

wherein,
ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and
Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula I are C(O)), aromatic hydroxycarboxylic repeating units (Y₁ is 0 and Y₂ is C(O) in Formula I), as well as various combinations thereof.

Aromatic hydroxycarboxylic repeating units, for instance, may be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute about 20 mol. % to about 80 mol. %, in some embodiments from about 25 mol. % to about 75 mol. %, and in some embodiments, from about 30 mol. % to 70 mol. % of the polymer.

Aromatic dicarboxylic repeating units may also be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 1 mol. % to about 50 mol. %, in some embodiments from about 5 mol. % to about 40 mol. %, and in some embodiments, from about 10 mol. % to about 35 mol. % of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 40 mol. %, in some embodiments from about 2 mol. % to about 35 mol. %, and in some embodiments, from about 5 mol. % to about 30 mol. % of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10 mol. % of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

Although by no means required, the liquid crystalline polymer may be a “high naphthenic” polymer to the extent that it contains a relatively high content of repeating units derived from naphthenic hydroxycarboxylic acids and naphthenic dicarboxylic acids, such as NDA, HNA, or combinations thereof. That is, the total amount of repeating units derived from naphthenic hydroxycarboxylic and/or dicarboxylic acids (e.g., NDA, HNA, or a combination of HNA and NDA) is typically about 10 mol. % or more, in some embodiments about 12 mol. % or more, in some embodiments about 15 mol. % or more, in some embodiments from about 15 mol. % to about 50 mol. %, and in some embodiments, from 16 mol. % to about 30 mol. % of the polymer. In one embodiment, for instance, the repeating units derived from NDA are within the ranges noted above. The liquid crystalline polymer may also contain various other monomers. For example, the polymer may contain repeating units derived from HBA in an amount of from about 20 mol. % to about 60 mol. %, and in some embodiments from about 25 mol. % to about 55 mol. %, and in some embodiments, from about 30 mol. % to about 50 mol. %. The polymer may also contain aromatic dicarboxylic acid(s) (e.g., IA and/or TA) in an amount of from about 1 mol. % to about 15 mol. % and/or aromatic diol(s) (e.g., BP and/or HQ) in an amount of from about 10 mol. % to about 35 mol. %. Of course, in other embodiments, the liquid crystalline polymer may be a “low naphthenic” polymer to the extent that it contains a relatively low content of repeating units derived from naphthenic hydroxycarboxylic acids and naphthenic dicarboxylic acids, such as naphthalene-2,6-dicarboxylic acid (“NDA”), 6-hydroxy-2-naphthoic acid (“HNA”), or combinations thereof. That is, the total amount of repeating units derived from naphthenic hydroxycarboxylic and/or dicarboxylic acids (e.g., NDA, HNA, or a combination of HNA and NDA) may be about 10 mol. % or less, in some embodiments about 8 mol. % or less, and in some embodiments, from about 1 mol. % to about 6 mol. % of the polymer.

It is often desired that a substantial portion of the polymer matrix is formed from such high naphthenic polymers. For example, high naphthenic polymers such as described herein typically constitute 50 wt. % or more, in some embodiments about 65 wt. % or more, in some embodiments from about 70 wt. % to 100 wt. %, and in some embodiments, from about 80 wt. % to 100% of the polymer matrix (e.g., 100 wt. %). In some cases, blends of polymers may also be used. For example, low naphthenic liquid crystalline polymers may constitute from about 1 wt. % to about 50 wt. %, in some embodiments from about 2 wt. % to about 40 wt. %, and in some embodiments, from about 5 wt. % to about 30 wt. % of the total amount of liquid crystalline polymers in the composition, and high naphthenic liquid crystalline polymers may constitute from about 50 wt. % to about 99 wt. %, in some embodiments from about 60 wt. % to about 98 wt. %, and in some embodiments, from about 70 wt. % to about 95 wt. % of the total amount of liquid crystalline polymers in the composition.

Of course, besides aromatic polymers, aliphatic polymers may also be suitable for use in the polymer matrix. In one embodiment, for instance, polyamides may be employed that generally have a CO—NH linkage in the main chain and are obtained by condensation of an aliphatic diamine and an aliphatic dicarboxylic acid, by ring opening polymerization of lactam, or self-condensation of an amino carboxylic acid. For example, the polyamide may contain aliphatic repeating units derived from an aliphatic diamine, which typically has from 4 to 14 carbon atoms. Examples of such diamines include linear aliphatic alkylenediamines, such as 1,4-tetramethylenediamine, 1,6-hexanediamine, 1,7-heptanediamine, 1,8-octanediamine, 1,9-nonanediamine, 1,10-decanediamine, 1,11-undecanediamine, 1,12-dodecanediamine, etc.; branched aliphatic alkylenediamines, such as 2-methyl-1,5-pentanediamine, 3-methyl-1,5 pentanediamine, 2,2,4-trimethyl-1,6-hexanediamine, 2,4,4-trimethyl-1,6-hexanediamine, 2,4-dimethyl-1,6-hexanediamine, 2-methyl-1,8-octanediamine, 5-methyl-1,9-nonanediamine, etc.; as well as combinations thereof. Aliphatic dicarboxylic acids may include, for instance, adipic acid, sebacic acid, etc. Particular examples of such aliphatic polyamides include, for instance, nylon-4 (poly-α-pyrrolidone), nylon-6 (polycaproamide), nylon-11 (polyundecanamide), nylon-12 (polydodecanamide), nylon-46 (polytetramethylene adipamide), nylon-66 (polyhexamethylene adipamide), nylon-610, and nylon-612. Nylon-6 and nylon-66 are particularly suitable.

It should be understood that it is also possible to include aromatic monomer units in the polyamide such that it is considered aromatic (contains only aromatic monomer units are both aliphatic and aromatic monomer units). Examples of aromatic dicarboxylic acids may include, for instance, terephthalic acid, isophthalic acid, 2,6-naphthalenedicarboxylic acid, 2,7-naphthalenedicarboxylic acid, 1,4-naphthalenedicarboxylic acid, 1,4-phenylenedioxy-diacetic acid, 1,3-phenylenedioxy-diacetic acid, diphenic acid, 4,4′-oxydibenzoic acid, diphenylmethane-4,4′-dicarboxylic acid, diphenylsulfone-4,4′-dicarboxylic acid, 4,4′-biphenyldicarboxylic acid, etc. Particularly suitable aromatic polyamides may include poly(nonamethylene terephthalarnide) (PA9T), poly(nonamethylene terephthalamide/nonamethylene decanediamide) (PA9T/910), poly(nonamethylene terephthalamide/nonamethylene dodecanediamide) (PA9T/912), poly(nonamethylene terephthalamide/11-aminoundecanamide) (PA9T/11), poly(nonamethylene terephthalamide/12-aminododecanamide) (PA9T/12), poly(decamethylene terephthalamide/11-aminoundecanamide) (PA10T/11), poly(decamethylene terephthalamide/12-aminododecanamide) (PA10T/12), poly(decamethylene terephthalamide/decamethylene decanediamide) (PA10T/1010), poly(decamethylene terephthalamide/decamethylene dodecanediamide) (PA10T/1012), poly(decamethylene terephthalamide/tetramethylene hexanediamide) (PA10T/46), poly(decamethylene terephthalamide/caprolactam) (PA10T/6), poly(decamethylene terephthalamide/hexamethylene hexanediamide) (PA10T/66), poly(dodecamethylene terephthalamide/dodecamethylene dodecanediarnide) (PA12T/1212), poly(dodecamethylene terephthalamide/caprolactam) (PA12T/6), poly(dodecamethylene terephthalamide/hexamethylene hexanediamide) (PA12T/66), and so forth.

The polyamide is typically crystalline or semi-crystalline in nature and thus has a measurable melting temperature. The melting temperature may be relatively high such that the composition can provide a substantial degree of heat resistance to a resulting part. For example, the polyamide may have a melting temperature of about 220° C. or more, in some embodiments from about 240° C. to about 325° C., and in some embodiments, from about 250° C. to about 335° C. The polyamide may also have a relatively high glass transition temperature, such as about 30° C. or more, in some embodiments about 40° C. or more, and in some embodiments, from about 45° C. to about 140° C. The glass transition and melting temperatures may be determined as is well known in the art using differential scanning calorimetry (“DSC”), such as determined by ISO Test No. 11357-2:2020 (glass transition) and 11357-3:2018 (melting).

### B. Optional Components

If desired, the polymer matrix may constitute the entire composition. In other embodiments, however, one or more optional components can also be incorporated into the polymer composition to achieve certain properties, such as thermally conductive fillers, mineral fillers, electrically conductive fillers, plating additives, reinforcing fibers (e.g. glass fibers), impact modifiers, lubricants, pigments (e.g., carbon black), antioxidants, stabilizers, surfactants, waxes, flame retardants, anti-drip additives, nucleating agents (e.g., boron nitride), and other materials added to enhance properties and processability.

In one embodiment, for example, the polymer composition may contain a thermally conductive filler distributed within the polymer matrix. When employed, to help achieve the desired balance between thermal conductivity, heat resistance, high flow, and good mechanical properties, the relative amount of the thermally conductive filler may be controlled to be within a range of from about 10 to about 250 parts by weight, in some embodiments from about 40 to about 250 parts by weight, in some embodiments from about 60 to about 200 parts by weight, and in some embodiments, from about 80 to about 190 parts by weight per 100 parts by weight of the polymer matrix. The thermally conductive filler may, for instance, constitute from about 20 wt. % to about 70 wt. %, in some embodiments from about 28 wt. % to about 62 wt. %, in some embodiments from about 35 wt. % to about 65 wt. %, and in some embodiments, from about 40 wt. % to about 60 wt. % of the polymer composition. The resulting polymer composition may exhibit a high thermal conductivity that allows the composition to be capable of creating a thermal pathway for heat transfer away from elements of the projector. In this manner, “hot spots” can be quickly eliminated and the overall temperature can be lowered during use. The polymer composition may, for example, exhibit an in-plane (or “flow”) thermal conductivity of about 1 W/m-K or more, in some embodiments about 1.5 W/m-K or more, in some embodiments about 2 W/m-K or more, in some embodiments from about 2.5 to about 15 W/m-K, in some embodiments about 3 to about 10 W/m-K, and in some embodiments, from about 4 to about 8 W/m-K, as determined in accordance with ASTM E 1461-13(2022). Similarly, the polymer composition may exhibit a cross-plane (or “cross-flow”) thermal conductivity of about 0.8 W/m-K or more, in some embodiments from about 1 to about 12 W/m-K, and in some embodiments, from about 2 to about 8 W/m-K, as determined in accordance with ASTM E 1461-13(2022). The composition may also exhibit a through-plane thermal conductivity of about 0.2 W/m-K or more, in some embodiments about 0.3 W/m-K or more, in some embodiments about 0.5 to about 4 WV/m-K, and in some embodiments, from about 0.6 to about 2 W/m-K, as determined in accordance with ASTM E 1461-13(2022).

If desired, the thermally conductive filler may include a material having a high degree of intrinsic thermal conductivity. For example, the polymer composition may be contain a material having an intrinsic thermal conductivity of 50 W/m-K or more, in some embodiments 100 W/m-K or more, and in some embodiments, 150 W/m-K or more. Examples of such high intrinsic thermally conductive materials may include, for instance, boron nitride, aluminum nitride, magnesium silicon nitride, graphite (e.g., expanded graphite), silicon carbide, carbon nanotubes, zinc oxide, magnesium oxide, beryllium oxide, zirconium oxide, yttrium oxide, aluminum powder, and copper powder. While such materials having a high intrinsic conductivity can certainly be employed in certain embodiments, a high degree of thermal conductivity can also be achieved without use of conventional materials having a high degree of intrinsic thermal conductivity. For example, the polymer composition may be generally free of fillers having an intrinsic thermal conductivity. That is, such fillers may constitute about 10 wt. % or less, in some embodiments about 5 wt. % or less, and in some embodiments, from 0 wt. % to about 2 wt. % of the polymer composition (e.g., 0 wt. %).

In one particular embodiment, for instance, the thermally conductive filler may contain mineral particles. When employed, such mineral particles typically constitute from about 70 to about 250 parts by weight, in some embodiments from about 75 to about 200 parts by weight, and in some embodiments, from about 90 to about 190 parts by weight per 100 parts by weight of the polymer matrix. The mineral particles may, for instance, constitute from about 30 wt. % to about 70 wt. %, in some embodiments from about 35 wt. % to about 65 wt. %, and in some embodiments, from about 40 wt. % to about 60 wt. % of the polymer composition. The mineral particles may be formed from a natural and/or synthetic silicate mineral, such as talc, mica, halloysite, kaolinite, illite, montmorillonite, vermiculite, palygorskite, pyrophyllite, calcium silicate, aluminum silicate, wollastonite, etc. Talc is particularly suitable for use in the polymer composition. The shape of the particles may vary as desired, such as granular, flake-shaped, etc. The particles typically have a median particle diameter (D50) of from about 1 to about 25 micrometers, in some embodiments from about 2 to about 15 micrometers, and in some embodiments, from about 4 to about 10 micrometers, as determined by sedimentation analysis (e.g., Sedigraph 5120). If desired, the particles may also have a high specific surface area, such as from about 1 square meters per gram (m²/g) to about 50 m²/g, in some embodiments from about 1.5 m²/g to about 25 m²/g, and in some embodiments, from about 2 m²/g to about 15 m²/g. Surface area may be determined by the physical gas adsorption (BET) method (nitrogen as the adsorption gas) in accordance with DIN 66131:1993. The moisture content may also be relatively low, such as about 5% or less, in some embodiments about 3% or less, and in some embodiments, from about 0.1 to about 1% as determined in accordance with ISO 787-2:1981 at a temperature of 105° C.

In addition to and/or in lieu of mineral particles, the thermally conductive filler may also contain mineral fibers (also known as “whiskers”). When employed, such mineral fibers typically constitute from about 10 to about 150 parts by weight, in some embodiments from about 15 to about 100 parts by weight, and in some embodiments, from about 20 to about 80 parts by weight per 100 parts by weight of the polymer matrix. The mineral fibers may, for instance, constitute from about 10 wt. % to about 50 wt. %, in some embodiments from about 15 wt. % to about 45 wt. %, and in some embodiments, from about 20 wt. % to about 40 wt. % of the polymer composition. Examples of such mineral fibers include those that are derived from silicates, such as nesosilicates, sorosilicates, inosilicates (e.g., calcium inosilicates, such as wollastonite; calcium magnesium inosilicates, such as tremolite; calcium magnesium iron inosilicates, such as actinolite; magnesium iron inosilicates, such as anthophyllite; etc.), phyllosilicates (e.g., aluminum phyllosilicates, such as palygorskite), tectosilicates, etc.; sulfates, such as calcium sulfates (e.g., dehydrated or anhydrous gypsum); mineral wools (e.g., rock or slag wool); and so forth. Particularly suitable are inosilicates, such as wollastonite fibers available from Nyco Minerals under the trade designation NYGLOS® (e.g. NYGLOS®4 W or NYGLOS®8). The mineral fibers may have a median diameter of from about 1 to about 35 micrometers, in some embodiments from about 2 to about 20 micrometers, in some embodiments from about 3 to about 15 micrometers, and in some embodiments, from about 7 to about 12 micrometers. The mineral fibers may also have a narrow size distribution. That is, at least about 60% by volume of the fibers, in some embodiments at least about 70% by volume of the fibers, and in some embodiments, at least about 80% by volume of the fibers may have a size within the ranges noted above. In addition to possessing the size characteristics noted above, the mineral fibers may also have a relatively high aspect ratio (average length divided by median diameter) to help further improve the mechanical properties and surface quality of the resulting polymer composition. For example, the mineral fibers may have an aspect ratio of from about 2 to about 100, in some embodiments from about 2 to about 50, in some embodiments from about 3 to about 20, and in some embodiments, from about 4 to about 15. The volume average length of such mineral fibers may, for example, range from about 1 to about 200 micrometers, in some embodiments from about 2 to about 150 micrometers, in some embodiments from about 5 to about 100 micrometers, and in some embodiments, from about 10 to about 50 micrometers.

The polymer composition may also contain a variety of other optional components to help improve its overall properties. For example, the polymer composition may contain a metal hydroxide that is effectively capable of “losing” hydroxide ions during processing with the polymer to initiate chain scission of the polymer, which reduces molecular weight, and in turn, the melt viscosity of the polymer under shear. When employed, the metal hydroxide(s) may constitute from about 0.05 to about 10 parts, in some embodiments from about 0.1 to about 5 parts, and in some embodiments, from about 0.2 to about 3 parts by weight per 100 parts by weight of the polymer matrix. For example, the metal hydroxide(s) may constitute from about 0.01 wt. % to about 5 wt. %, in some embodiments from about 0.05 wt. % to about 4 wt. %, and in some embodiments, from about 0.1 wt. % to about 2 wt. % of the polymer composition. One example of a suitable metal hydroxide has the general formula M(OH)ₛ, where s is the oxidation state (typically from 1 to 3) and M is a metal, such as a transitional metal, alkali metal, alkaline earth metal, or main group metal. Examples of suitable metal hydroxides may include copper (II) hydroxide (Cu(OH)₂), potassium hydroxide (KOH), sodium hydroxide (NaOH), magnesium hydroxide (Mg(OH)₂), calcium hydroxide (Ca(OH)₂), aluminum hydroxide (Al(OH)₃), and so forth. Also suitable are metal alkoxide compounds that are capable of forming a hydroxyl functional group in the presence of a solvent, such as water. Such compounds may have the general formula M(OR)ₛ, wherein s is the oxidation state (typically from 1 to 3), M is a metal, and R is alkyl. Examples of such metal alkoxides may include copper (II) ethoxide (Cu²⁺(CH₃CH₂O⁻)₂), potassium ethoxide (K⁺(CH₃CH₂O⁻)), sodium ethoxide (Na⁺(CH₃CH₂O⁻)), magnesium ethoxide (Mg²⁺(CH₃CH₂O⁻)₂), calcium ethoxide (Ca²⁺(CH₃CH₂O⁻)₂), etc.; aluminum ethoxide (Al³⁺(CH₃CH₂O⁻)₃), and so forth. In particular embodiments, the metal hydroxide may be in the form of metal hydroxide particles. For instance, the particles may contain at least one aluminum hydroxide having the general formula: Al(OH)ₐO_{b}, where 0≤a≤3 (e.g., 1) and b=(3−a)/2. In one particular embodiment, for example, the particles exhibit a boehmite crystal phase and the aluminum hydroxide has the formula AlO(OH) (“aluminum oxide hydroxide”). The metal hydroxide particles may be needle-shaped, ellipsoidal-shaped, platelet-shaped, spherical-shaped, etc. Regardless, the particles typically have a median particle diameter (D50) of from about 50 to about 800 nanometers, in some embodiments from about 150 to about 700 nanometers, and in some embodiments, from about 250 to about 500 nanometers, as determined by non-invasive back scatter (NIBS) techniques. If desired, the particles may also have a high specific surface area, such as from about 2 square meters per gram (m²/g) to about 100 m²/g, in some embodiments from about 5 m²/g to about 50 m²/g, and in some embodiments, from about 10 m²/g to about 30 m²/g. Surface area may be determined by the physical gas adsorption (BET) method (nitrogen as the adsorption gas) in accordance with ISO 9277:2010. The moisture content may also be relatively low, such as about 5% or less, in some embodiments about 3% or less, and in some embodiments, from about 0.1 to about 1% as determined in accordance with ISO 787-2:1981.

Electrically conductive fillers may also be employed in the polymer composition, such as those having an intrinsic volume resistivity of less than about 1 ohm-cm, in some embodiments about less than about 0.1 ohm-cm, and in some embodiments, from about 1×10⁻⁸ to about 1×10⁻² ohm-cm, such as determined at a temperature of about 20° C. Examples of such electrically conductive fillers may include, for instance, electrically conductive carbon materials such as, graphite, electrically conductive carbon black, carbon fibers, graphene, carbon nanotubes, etc.; metals (e.g., metal particles, metal flakes, metal fibers, etc.); ionic liquids; and so forth. In certain embodiments, as noted above, the polymer composition is insulative in nature and thus has a high degree of electrical resistance. In such embodiments, it may be desired that the composition is generally free of electrically conductive fillers as described above, such as containing no more than about 5 wt. %, in some embodiments no more than about 2 wt. %, in some embodiments no more than about 1 wt. %, in some embodiments no more than about 0.5 wt. %, and in some embodiments, from 0 wt. % to about 0.2 wt. % of such electrically conductive fillers.

In certain embodiments, reinforcing fibers may employed to help improve the mechanical properties of the polymer composition. Examples of such reinforcing fibers includes those formed from materials that are insulative in nature, such as glass, ceramics (e.g., alumina or silica), aramids (e.g., Kevlar®), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. The reinforcing fibers may be in the form of randomly distributed fibers, such as when such fibers are melt blended with the high performance polymer(s) during the formation of the polymer matrix. Alternatively, the reinforcing fibers may be in the form of long fibers and impregnated with the polymer matrix in a manner such as described above. Regardless, the volume average length of the reinforcing fibers may be from about 1 to about 400 micrometers, in some embodiments from about 50 to about 400 micrometers, in some embodiments from about 80 to about 250 micrometers, in some embodiments from about 100 to about 200 micrometers, and in some embodiments, from about 110 to about 180 micrometers. The fibers may also have an average diameter of about 10 to about 35 micrometers, and in some embodiments, from about 15 to about 30 micrometers. While reinforcing fibers may be employed, the polymer composition may also be capable of achieving a high degree of mechanical strength without the need such fibers. In this regard, the polymer composition may be generally free of reinforcing fibers, such as no more than about 20 wt. %, in some embodiments no more than about 10 wt. %, and in some embodiments, from about 0 wt. % to about 5 wt. % of reinforcing fibers.

Regardless of the particular types of components employed, they may generally be melt processed or blended together with the polymer matrix in a variety of ways. For example, the components may be supplied separately or in combination to an extruder that includes at least one screw rotatably mounted and received within a barrel (e.g., cylindrical barrel) and may define a feed section and a melting section located downstream from the feed section along the length of the screw. The extruder may be a single screw or twin screw extruder. The speed of the screw may be selected to achieve the desired residence time, shear rate, melt processing temperature, etc. For example, the screw speed may range from about 50 to about 800 revolutions per minute (“rpm”), in some embodiments from about 70 to about 150 rpm, and in some embodiments, from about 80 to about 120 rpm. The apparent shear rate during melt blending may also range from about 100 seconds' to about 10,000 seconds⁻¹, in some embodiments from about 500 seconds⁻¹ to about 5000 seconds⁻¹, and in some embodiments, from about 800 seconds⁻¹ to about 1200 seconds⁻¹. The apparent shear rate is equal to 4Q/πR³, where Q is the volumetric flow rate (“m³/s”) of the polymer melt and R is the radius (“m”) of the capillary (e.g., extruder die) through which the melted polymer flows.

### II. Projector

Although any suitable shaped part can be formed, the polymer composition of the present invention is particularly suitable for use in a projector (e.g., nanoprojector, picoprojector, microprojector, femtoprojector, LASER-based projector, holographic projector, etc.) of a head-mounted, virtual, mixed, and/or augmented reality system. The projector generally includes an optical display that is capable of producing a visual image derived from light emitted by an illumination source. The display may include a liquid crystal display (“LCD”) (e.g., liquid crystal on silicon (“LCoS”), ferroelectric LCOs (“FLCoS”), back-lit LCD, front-lit LCD, transflective LCD, transparent liquid crystal micro-displays, etc.), organic light-emitting diode display (“OLED”), field emission display (“FED”), quantum-dot displays, and so forth. The illumination source may emit coherent and/or partially coherent light and may include, for instance, a light-emitting diode (e.g., RGB LED, phosphor-based LED, OLED, superluminescent light emitting diode (SLED) with high spatial coherency, etc.); laser diode (e.g., infrared vertical-cavity surface-emitting laser (VCSEL), distributed feedback laser (DFB), etc.); and so forth. The projector may also contain an optical waveguide that receives image light from the optical display. The image light may be reflected into the optical waveguide such that it engages in total internal reflections (TIR) until reaching the active viewing area of one or more lenes (e.g., transparent or translucent) of the head-mounted display, thus allowing a user to see the resulting visual image produced by the projector. If desired, the projector may also contain other optical components as is known in the art, such as a polarizer (e.g., linear polarizer, reflective polarizer, etc.), lens elements (e.g., plano-convex lens, condenser lens, field lens, etc.), beam splitter, wave plates, etc., to allow light to pass through and/or reflect from surfaces to provide the desired lens power. A processor, which may include a memory and an operating system, may also be employed to help control the illumination source and the optical display.

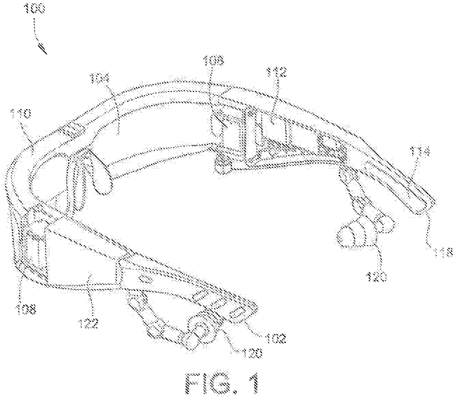

The head-mounted display system may be provided in a variety of different forms depending on the particular application, such as in the form of glasses, helmets, goggles, etc. Referring to FIG. 1, one particular embodiment of a head-mounted display system 100 is shown in the form of glasses for use in an augmented reality system. In the illustrated embodiment, one or more projectors 108 are provided for generating a visual image onto or through at least one lens 104 disposed in an opening of a frame 102 of the display system 100. Although by no means required, the projector(s) may be connected to the frame, lenses, or a combination thereof. In the illustrated embodiment, for instance, the projectors 108 are disposed in the arm portion of the frame 102. In certain cases, both lenses 104 may be transparent or translucent, while in other embodiments, only one lens 104 may be transparent or translucent while the other is opaque or missing. As shown, the display system 100 may also include various optional components, such as an articulating ear bud 120, radio transceiver 118, heat sink 114 to absorb heat from the light source, TI OMAP4 (open multimedia applications processors) 112, flex cable with an RF antenna 110, etc. The display system 100 may also be powered by any power supply (not shown), such as battery power, solar power, line power, and so forth. The power source may be integrated in the frame 102 or disposed external to the display system 100 and in electrical communication with the powered elements of the display system 100.

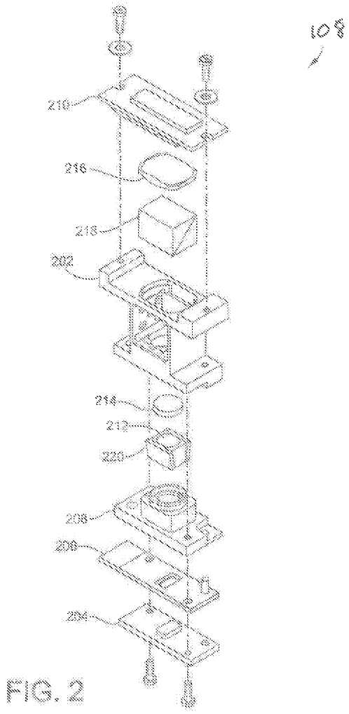

Referring to FIG. 2, one particular embodiment of the projector 108 is shown in more detail. In this particular embodiment, the projector 108 may include a housing 202 that supports and/or receives an illumination source 206 (e.g., RGB LED engine or module) and an optical display 210. If desired, the illumination source 206 may be mounted on a heat sink 204 to help with thermal management and a holder 208 to help minimize vibration. The projector 108 may also include a hollow tapered light tunnel 220 that can help homogenize rapidly-varying light from the illumination source 206. A diffuser lens 212 may likewise be employed to further homogenize and mix the light before being led to a condenser lens 214. The projector 108 may also include a polarizing beam splitter 218 that receives light from the condenser lens 214, and thus propagates and splits the light into polarization components before it is refracted to the optical display 210 through an optional field lens 216.

As noted above, the optical display 210 may provide the image for the projector. A digital signal processor (DSP) (not shown) may convert the images or video stream into control signals, such as voltage drops/current modifications, pulse width modulation (PWM) signals, and so forth to control the intensity, duration, and mixing of the LED light. For example, the DSP may control the duty cycle of each PWM signal to control the average current flowing through the illumination source generating a plurality of colors. A still image co-processor may employ noise-filtering, image/video stabilization, and face detection, and be able to make image enhancements. An audio back-end processor may employ buffering, SRC, equalization and so forth. The head-mounted display system may also include an optical waveguide that enables internal reflections. In this manner, light from the illumination source may be emitted and traverse through an optional polarizing beam splitter where it is polarized, reflected off the optical display, and then directed into the optical waveguide. A corrective element may be employed (e.g., lens) that is attached to the optical waveguide to enable proper viewing of the surrounding environment whether the image source is on or off. The optical waveguide (e.g., freeform) may include dual freeform surfaces that enable a curvature and a sizing of the waveguide. The curvature and the sizing of the waveguide enable its placement in the frame of the interactive head-mounted display system.

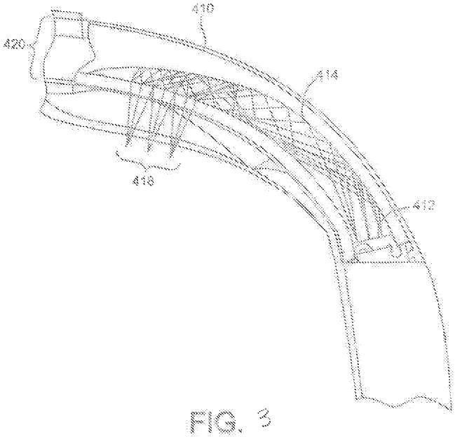

Referring to FIG. 3, for instance, one embodiment is shown in which the image light from the optical display, which may be polarized and collimated, may optionally traverse a display coupling lens 412 and enter a waveguide 414. In some embodiments, the waveguide 414 may be a freeform waveguide, where the surfaces of the waveguide are described by a polynomial equation. The waveguide 414 may be rectilinear and may include two reflective surfaces. When the image light enters the waveguide 414, it may strike a first surface with an angle of incidence greater than the critical angle above which total internal reflection (TIR) occurs. The image light may engage in TIR bounces between the first surface and a second facing surface, eventually reaching the active viewing area 418 of the composite lens. In one embodiment, light may engage in at least three TIR bounces. Because the waveguide 414 tapers to enable the TIR bounces to eventually exit the waveguide, the thickness of the composite lens 420 may not be uniform. Distortion through the viewing area of the composite lens 420 may be minimized by disposing a wedge-shaped correction lens 410 along a length of the freeform waveguide 414 in order to provide a uniform thickness across at least the viewing area of the lens 420. The correction lens 410 may be a prescription lens, a tinted lens, a polarized lens, a ballistic lens, and so forth. In some embodiments, while the optical waveguide may have a first surface and a second surface enabling total internal reflections of the light entering the waveguide, the light may not actually enter the waveguide at an internal angle of incidence that would result in total internal reflection. The display system may include a mirrored surface on the first surface of the optical waveguide to reflect the displayed content towards the second surface of the optical waveguide. Thus, the mirrored surface enables a total reflection of the light entering the optical waveguide or a reflection of at least a portion of the light entering the optical waveguide. In embodiments, the surface may be 100% mirrored or mirrored to a lower percentage. In some embodiments, in place of a mirrored surface, an air gap between the waveguide and the corrective element may cause a reflection of the light that enters the waveguide at an angle of incidence that would not result in TIR.

Generally speaking, any portion of the projector 108 shown in FIGS. 1-3 may contain the polymer composition described herein. For example, the polymer composition may be used to form all or a portion of various structural components of the projector, such as the housing 202, heat sink 204, holder 208, etc. The polymer composition may also be used in one or more optical components, such as the illumination source 206, optical display 210, tunnel 220, condenser lens 214, field lens 216, coupling lens 412, waveguide 414, etc. In such embodiments, the polymer composition be used to form a support, frame, and/or housing for such optical components. Of course, the polymer composition may also be used in various other locations of the head-mounted display system 100, such as in all or a portion of the frame 102, heat sink 114, RF antenna 110, etc.

The following test methods may be employed to determine the properties referenced herein.

### Test Methods

Thermal Conductivity: As is known in the art, the thermal diffusivity of a sample in various directions (in-plane, cross-plane, through-plane) may be initially determined based on the laser flash method in accordance with ASTM E1461-13(2022). The thermal conductivity (in-plane, cross-plane, and through-plane) may then be calculated according to the following formula: Thermal Conductivity (W/m*K)=Cp*ρ*α, where Cp is the specific heat capacity (J/kgK) of the sample, ρ is the intrinsic density (kg/m³) of the sample as determined in accordance with ISO 11831-1:2019 (Method A), and a is the measured thermal diffusivity (m²/s).

Melt Viscosity: The melt viscosity (Pa-s) may be determined in accordance with ISO 11443:2021 at a shear rate of 400 s⁻¹, 1,000 s⁻¹ or 1,200⁻¹. The preferred shear rate may vary as is known in the art. Liquid crystalline polymer systems, for example, may be tested at a shear rate of 1,000 s⁻¹, while polyarylene sulfide systems may be tested at a shear rate of 1,200 s⁻¹. The viscosity may be determined using a capillary rheometer, such as a Dynisco LCR7001 capillary rheometer. The rheometer orifice (die) may have a diameter of 1 mm, length of 20 mm, L/D ratio of 20.1, and an entrance angle of 180°. The diameter of the barrel may be 9.55 mm+0.005 mm and the length of the rod may be 233.4 mm. The melt viscosity is typically determined at a temperature above the melting temperature of the polymer and/or composition. As is known in the art, this temperature may vary depending on the particular polymer system employed. For liquid crystalline polymer systems, for example, the melt viscosity may be tested at a temperature of about 15° C. above the melting temperature of the polymer and/or polymer composition (e.g., 365° C. for a liquid crystalline polymer having a melting temperature of about 350° C.). Polyarylene sulfide systems, on the other hand, may be tested at a temperature of about 30° C. to 36° C. above the melting temperature of the polymer and/or polymer composition (e.g., 310° C. for a polyarylene sulfide having a melting temperature of about 280° C.).

Melting Temperature: The melting temperature (“Tm”) may be determined by differential scanning calorimetry (“DSC”) as is known in the art. The melting temperature is the differential scanning calorimetry (DSC) peak melt temperature as determined by ISO Test No. 11357-3:2018. Under the DSC procedure, samples were heated and cooled at 20° C. per minute as stated in ISO Standard 10350 using DSC measurements conducted on a TA Q2000 Instrument.

Tensile Modulus, Tensile Stress at Break, and Tensile strain at Break Tensile properties may be tested according to ISO 527:2019 (technically equivalent to ASTM D638-14). Modulus and strength measurements may be made on the same test strip sample having a length of 80 mm, thickness of 10 mm, and width of 4 mm. The testing temperature may be 23° C., and the testing speeds may be 5 mm/min for tensile strength and tensile strain at break, and 1 mm/min for tensile modulus.

Flexural Modulus and Flexural Stress: Flexural properties may be tested according to ISO 178:2019 (technically equivalent to ASTM D790-10). This test may be performed on a 64 mm support span. Tests may be run on the center portions of uncut ISO 3167 multi-purpose bars. The testing temperature may be 23° C. and the testing speed may be 2 mm/min.

Charpy impact Strength: Charpy properties may be tested according to ISO 179-1:2010) (technically equivalent to ASTM D256-10, Method B). This test may be run using a Type 1 specimen size (length of 80 mm, width of 10 mm, and thickness of 4 mm). Specimens may be cut from the center of a multi-purpose bar using a single tooth milling machine. The testing temperature may be 23° C. For “notched” impact strength, this test may be run using a Type A notch (0.25 mm base radius) and Type 1 specimen size (length of 80 mm, width of 10 mm, and thickness of 4 mm).

Comparative Tracking Index (“CTI”): The comparative tracking index (CTI) may be determined in accordance with International Standard IEC 60112-2003 to provide a quantitative indication of the ability of a composition to perform as an electrical insulating material under wet and/or contaminated conditions. In determining the CTI rating of a composition, two electrodes are placed on a molded test specimen. A voltage differential is then established between the electrodes while a 0.1% aqueous ammonium chloride solution is dropped onto a test specimen. The maximum voltage at which five (5) specimens withstand the test period for 50 drops without failure is determined. The test voltages range from 100 to 600 V in 25 V increments. The numerical value of the voltage that causes failure with the application of fifty (50) drops of the electrolyte is the “comparative tracking index.” The value provides an indication of the relative track resistance of the material. According to UL746A, a nominal part thickness of 3 mm is considered representative of performance at other thicknesses.

Dimensional Stability: The degree of shrinkage of a sample in a given direction may be determined in accordance with ISO 294-4:2018. For example, parts may be injection molded with a mold cavity having a machine direction dimension or length (Lₘ) of 60 mm, a transverse dimension or width (Wₘ) of 60 mm, and a height dimension (Hₘ) of 2 mm, which conforms to a Type D2 specimen. The average length (Lₛ) and width (Wₛ) of five (5) test specimens may be measured after removal from the mold and cooling. The shrinkage in the flow (or length) direction (S_{F}) may be calculated by S_{F}=(Lₘ−Lₛ)×100/Lₘ and the shrinkage in the transverse (or width) direction (S_{T}) may be calculated by S_{T}=(Wₘ−Wₛ)×100/Wₘ. The “dimensional stability” may thereafter be determined by dividing the degree of shrinkage in the transverse direction by the degree of shrinkage in the machine direction.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

1. A projector for use in a head-mounted display system, wherein the projector comprises an illumination source and an optical display that is capable of producing an image derived from light emitted by the illumination source, wherein the projector contains a polymer matrix that contains a thermoplastic polymer, wherein the polymer composition exhibits a deflection temperature under load of about 50° C. or more as determined in accordance with ISO 75:2013 at a load of 1.8 MPa.

2. The projector of claim 1, wherein the polymer composition exhibits a melt viscosity of about 300 Pa-s or less as determined in accordance with ISO 11443:2021 at a shear rate of 1,000 s⁻¹ and temperature above the melting temperature of the composition.

3. The projector of claim 1, wherein the polymer composition exhibits an in-plane thermal conductivity of about 1 W/m-K or more as determined in accordance with ASTM E1461-13(2022).

4. The projector of claim 1, wherein the polymer composition exhibits a melting temperature of about 150° C. or more.

5. The projector of claim 1, wherein the polymer matrix includes an aromatic polymer.

6. The projector of claim 5, wherein the polymer matrix includes a thermotropic liquid crystalline polymer.

7. The projector of claim 6, wherein the thermotropic liquid crystalline polymer contains repeating units derived from one or more aromatic dicarboxylic acids, one or more aromatic hydroxycarboxylic acids, or a combination thereof.

8. The projector of claim 7, wherein the aromatic hydroxycarboxylic acids include 4-hydroxybenzoic acid, 6-hydroxy-2-naphthoic acid, or a combination thereof.

9. The projector of claim 8, wherein the aromatic dicarboxylic acids include terephthalic acid, isophthalic acid, 2,6-naphthalenedicarboxylic acid, or a combination thereof.

10. The projector of claim 7, wherein the liquid crystalline polymer further contains repeating units derived from one or more aromatic diols.

11. The projector of claim 10, wherein the aromatic diols include hydroquinone, 4,4′-biphenol, or a combination thereof.

12. The projector of claim 6, wherein the thermotropic liquid crystalline polymer is wholly aromatic.

13. The projector of claim 5, wherein the polymer matrix includes a polyarylene sulfide.

14. The projector of claim 5, wherein the polymer matrix includes an aromatic polyester.

15. The projector of claim 1, wherein the polymer composition exhibits a dielectric strength of about 10 kilovolts per millimeter or more as determined in accordance with IEC 60234-1:2013.

16. The projector of claim 1, wherein the polymer composition exhibits a comparative tracking index of about 170 volts or more as determined in accordance with IEC 60112:2003 at a thickness of 3 millimeters.

17. The projector of claim 1, wherein the polymer composition contains a thermally conductive filler.

18. The projector of claim 17, wherein the thermally conductive filler includes mineral particles, mineral fibers, or a combination thereof.

19. The projector of claim 1, wherein the polymer composition contains reinforcing fibers.

20. The projector of claim 1, wherein the optical display includes a liquid crystal display, organic light-emitting diode display, field emission display, quantum-dot display, or a combination thereof.

21. The projector of claim 1, wherein the illumination source includes a laser diode, light-emitting diode, or a combination thereof.

22. The projector of claim 1, further comprising a housing that supports and/or receives the illumination source and the optical display, wherein the housing comprises the polymer composition.

23. The projector of claim 1, wherein the illumination source is mounted to a heat sink and/or holder, wherein the heat sink, the holder, or both comprise the polymer composition.

24. The projector of claim 1, further comprising an optical waveguide that receives image light from the optical display.

25. A head-mounted display system comprising the projector of claim 1.

26. The head-mounted display system of claim 25, wherein the system contains one or more lenses disposed in an opening of a frame.

27. The head-mounted display system of claim 26, wherein the projector is connected to the frame, the lenses, or a combination thereof.
